(19) United States
(12) Patent Application Publication
(10) Pub. No.: US 2009/0302226 A1
(43) Pub. Date: Dec. 10, 2009

(54) SOLID-STATE NEUTRON AND ALPHA PARTICLES DETECTOR AND METHODS FOR MANUFACTURING AND USE THEREOF

(75) Inventors: Michael M. Schieber, Jerusalem (IL); Assaf Zuck, Jerusalem (IL); Gad Marom, Jerusalem (IL)

Correspondence Address: THE NATH LAW GROUP, 112 South West Street, Alexandria, VA, 22314, US

(73) Assignee: YISSUM RESEARCH DEVELOPMENT COMPANY OF THE HEBREW UNIVERSITY OF JERUSALEM, Jerusalem (IL)

(21) Appl. No.: 11/883,842

(22) PCT Filed: Feb. 8, 2006
(86) PCT No.: PCT/IL2006/000155

§ 371 Date: Feb. 4, 2009

Related U.S. Application Data
(60) Provisional application No. 60/650,520, filed on Feb. 8, 2005.

(51) Int. Cl. G01T 1/178; G01T 3/08; G01T 1/24; H01L 21/00; G01T 1/26

(52) U.S. Cl. 250/370.02; 250/370.05; 250/370.08; 438/56; 250/371; 257/E21.002

(57) ABSTRACT

A solid-state detector for detection of neutron and alpha particles detector and methods for manufacturing and use thereof are described. The detector has an active region formed of a polycrystalline semiconductor compound comprising a particulate semiconductor material sensitive to neutron and alpha particles radiation imbedded in a binder. The particulate semiconductor material contains at least one element sensitive to neutron and alpha particles radiation, selected from a group including 10Boron, 6Lithium, 113Cadmium, 157Gadolinium and 199Mercury. The semiconductor compound is sandwiched between an electrode assembly configured to detect the neutron and alpha particles interacting with the bulk of the active region. The binder can be either an organic polymer binder or inorganic binder. The organic polymer binder comprises at least one polymer that can be selected from the group comprising polystyrene, polypropylene, Humiseal™ and Nylon-6. The inorganic binder can be selected from B2O3, PbO/B2O3/, Bi2O3/PbO, Borax glass, Bismuth Borate glass and Boron Oxide based glass.

### FIELD OF THE INVENTION

This invention is generally in the field of neutron and alpha particles detection, and relates to a solid-state composite polycrystalline semiconductor detector and methods for manufacturing and use thereof.

### REFERENCES

The following references are considered to be pertinent for the purpose of understanding the description of the present invention:
1. U.S. Pat. No. 5,019,886 to Sato et. al.
2. U.S. Pat. No. 5,156,979 to Sato et. al.
3. U.S. Pat. No. 5,707,879 to Reintz.
4. Neutron detection with cryogenics and semiconductors, by Zane W Bell, et al., Phys. stat. sol. (c) 2., No 5, PP. 1592-1605, 2005.
5. D. S. McGregor, M. D. Hammig, Y.-H. Yang, H. K. Gersch, R T. Klann, “Design considerations for thin film coated semiconductor thermal neutron detectors—I: basics regarding alpha particle emitting neutron reactive films,” Nuclear Instruments and Methods in Physics Research, V. A “500, PP. 272-308, 2003.
6. D. S. McGregor, J. Kenneth Shultis, “Spectral identification of thin-film-coated and solid-form semiconductor neutron detectors,” Nuclear Instruments and Methods in Physics Research, V. A 517, PP. 180-188, 2004.
7. L. Gao and J Li J., Amer. Ceram. Soc., “Preparation of nanostructured hexagonal boron nitride powder,” vol. 86, P. 1982, 2003.
8. U.S. Pat. No. 6,388,260 to Doty et al.
9. U.S. Pat. No. 6,727,504 B1 to Doty et al.
10. U.S. Patent Application Publication No. 2004/0084626 to McGregor.
11. U.S. Patent Application Publication No. 2005/0067575 to Sane et al.
12. International Application WO 02/067014 A1 to Harel et al.
13. E. J. Robertson et al., Nuclear Instruments and Methods, A, V. 527 P. 554, 2004.

### BACKGROUND OF THE INVENTION

Neutron detectors generally may be divided into two categories, such as passive detectors, which can identify only signals of natural fission or induced fission emitted neutrons, and active detectors, which can also image and visualize the object detected by the passive detectors. Both active and passive detectors can be used for collecting image information under conditions which do not allow regular optical or X-ray imaging observation.

For example, a possible application of neutron detectors is the passive identification of neutron emitting nuclides and the active imaging of large containers at border crossing points, airports or naval ports. Since thermal neutrons can easily detect explosives and also other organic compounds such as drugs, and can penetrate the metallic container walls, they have advantages over X-ray or Gamma ray detection.

Most neutron detectors known today are based either on ³He Gas counters or plastic scintillators containing enriched Boron (¹⁰B) or Lithium isotope (⁶Li) [1-3]. The detection is based on conversion to visible light (scintillators), gamma rays or charged particles by nuclear reaction. The atoms of ¹⁰Boron (¹⁰B), ⁶Lithium (⁶Li), ¹¹³Cadmium (¹¹³Cd), ¹⁵⁷Gadolinium (¹⁵⁷Gd) or ¹⁹⁹Mercury (¹⁹⁹Hg) have a large cross section for capture of neutrons (see Table 1).

TABLE 1
Abundance, cross section and radiation energies
emitted by exemplary neutron sensitive nuclides

| | Abun- | Cross | |
|---|---|---|---|
| | dance | section | Thermal neutrons reactant |
| Nuclides | (%) | (Barns) | energies |
| ¹⁰B | 19.8 | 3,840 | ⁷Li(excited)0.84 MeV + alpha |
| | | | 1.47 MeV. |
| | | | ⁷Li(excited) decays to 480 keV |
| | | | gamma + ⁷Li(ground state)1.02 MeV |
| | | | and 1.78 MeV alpha |
| ¹⁹⁹Hg | 17.8 | 2,000 | 368 keV gamma |
| ¹⁵⁷Gd | 15.7 | 240,000 | gamma + beta below 220 keV |
| ⁶Li | 7.4 | 940 | 2.73 MeV tritium + 2.05 MeV alpha |
| ¹¹³Cd | 12.26 | 20,000 | 9 MeV + 558 keV + 651 keV gamma |

The cross-section given in the table is for thermal neutrons and the cross-sections decrease with the increase of the kinetic energy of the neutrons. For example, the cross-section σ of ¹⁰B varies from 3800 barns for thermal neutrons to a few barns for fast neutrons according to

$$σ \sim \frac{1}{\sqrt{E}} ,$$

where E is the neutron energy.

The absorption of neutron by ¹⁰B yields high energy Li and He (alpha) ions. The thermal neutrons have energy of 0.0259 eV and cause a nuclear reaction, to with:

₅¹⁰B+₀¹n→₂⁴He+₃⁷Li,

where 94% of the reaction produces ⁷Li, which is in the exited state at an energy of 0.84Mev, and quickly releases 0.48Mev of gamma emission to the ground state and releases also ⁴He ion or alpha particle at energy of 1.47 MeV. About 6% of the reaction of neutrons with ¹⁰B releases ⁷Li directly to the ground state at energy of 1.02 MeV and alpha particles of 1.777 MeV (see Table 1). The two ⁷Li and alpha emissions are emitted in opposite directions, thus making the efficiency dependent on the solid angle between the neutron trajectory and the emission of alpha particles. In 94% of the cases, the ⁷Li is in excited state and emits promptly a gamma ray of 477 keV. The ⁴He and the ⁷ Li particles have high kinetic energy and lose their energy by ionizing the surrounding atoms.

Similarly to ¹⁰B, ⁶Li reacts also with the same thermal neutrons of 0.0259 eV, to with:

⁶Li+¹n=H+⁴He (Alpha radiation)

where the 3H or Tritium atoms have kinetic energy of 2.73 MeV, the alpha particles have kinetic energy of 2.05 MeV and the cross section is 940 barns. Although the cross section is smaller for ⁶Li the detection is easier than in the case of ¹⁰B.

The other isotope elements capable to capture thermal neutrons with large cross sections but emit gamma rays are as follows: ¹¹³Cd, ¹⁵⁷Gd and ¹⁹⁹Hg.

For ¹¹³Cd the nuclear reaction is ¹¹³Cd+¹n=¹¹⁴Cd+γ. The discreet gamma (γ) emissions extend beyond 9 MeV and include easily measurable 558 and 651 keV emissions and a cross section of 20,000 barns.

For ¹⁵⁷Gd, with one of the largest cross sections for thermal neutrons of 240.000 Barns, the nuclear reaction is ¹⁵⁷Gd+¹n=¹⁵⁸Gd+γ+β. Both gamma (γ) and beta (β) rays are emitted at energies below 220 keV, which may be difficult to distinguish from background radiation.

For ¹⁹⁹Hg the reaction is ¹⁹⁹Hg+¹n=²⁰⁰Hg+γ. The reaction emits gamma rays at 368 keV with a cross section of 2000 barns

In all cases where thermal neutrons are captured by the large cross section isotopes present in a semiconductor compound, a large number of electron-hole pairs are produced by either the alpha or gamma or even beta rays (in the case of ¹⁵⁷Gd). By applying an electric field to the semiconductor, the charge carriers can be collected and create electric signals. This kind of detection is referred to as “direct conversion”, to distinguish from “indirect detection” in scintillators, where first visible light is produced, which in turn is transformed into electrical charges by means of a photomultiplier or photo diodes. It should be noted that the present invention refers to direct detection.

Room-temperature and cryogenic operated semiconductor detectors are also known in the art. A review of the different methods of neutron detection by room-temperature and cryogenic operated semiconductor detectors are described by Bell et al. [4]. It is pointed out that cryogenic detectors are limited due to the cooling by liquid Helium and are not useful for field instruments.

Two types of neutron semiconductor detectors are known in the art, such as thin film neutron sensitive detectors bulk and thick film (solid form or bulk) semiconductor detectors [5-11]. The main difference between the two types is the location where the nuclear interaction takes place.

In thin films detectors, a boron or lithium containing material, which is the neutron sensitive element, is deposited as a thin layer on a diode semiconductor device. The neutron interactions occur in a sensitive film adjacent to a diode detector, and the alpha particles formed enter the semiconductor diode and produce electrical charge carriers by ionization. The charge carriers are then separated by the electric field and collected by the electrodes.

FIG. 1 shows schematically a configuration of a simple thin-film-coated semiconductor diode neutron detector 10. A thin neutron reactive film 11 is applied directly to the rectifying contact surface 12 of a semiconductor diode 13. An applied voltage is used to drift the free charges liberated in the semiconductor diode apart thereby producing detectable charge induction.

Thin-film coated devices can be fabricated by applying one or more neutron reactive films upon the surface of a semiconductor diode. The reactive films can be applied using a number of different methods, including evaporation, sputtering, and chemical deposition. The diode is usually produced first, followed by the deposition of a thin coating of neutron reactive material on its surface(s). For example, when boron- and/or lithium-based coatings are used, the thickness of the coating can range from a few thousand angstroms to several microns. When neutrons interact within the film, only one of the charged particle reaction products, which are emitted in opposite directions, may pass through the detector interface into the diode.

On the other hand, in thick film (bulk) detectors the neutron interactions occur inside the bulk detector itself. In other words, thick film detectors use a semiconductor material composed, at least partially, of a neutron reactive material.

Referring to FIG. 2, a schematic illustration of a solid-form semiconductor diode neutron detector 20 is shown. The detector 20 includes a bulk semiconductor material 21 and a pair of electrodes 22 affixed on opposite sides 23 of the bulk material 21. The electrodes 22 are coupled to a power source 24 for applying a voltage across the bulk material. Neutrons can be absorbed directly within the detector. The interaction takes place in a large volume of the semiconductor material where the neutron impinges the sensitive element, which is a main component of a wide band gap semiconductor (e.g., ¹⁰BN, BP, BAs, HgI₂ and/or (Cd,Zn)Te) and the applied electric field drifts the electrical charges formed by the resulting alpha particles to the electrodes and from there to the imaging readout electronics.

It should be noted that, solid thick film bulk detectors are much more efficient than thin-film coated devices, since they employ a larger volume than the film. By using bulk semiconductor detectors sensitivity can be greatly increased, since the semiconductor sensitive layer serves both purposes, capturing the thermal neutrons and detection at the same time.

The research of boron based semiconductors could lead to a significant increase in the detection efficiency in the case of neutrons, but the fabrication of boron-based semiconductors is quite complicated. Either the material has no congruent melting point or the growth of these semiconductors requires processing at high temperatures. In order to produce this bulk semiconductor neutron detector for imaging purposes, it is suggested [5] to produce very large area epitaxial thick films, which in most cases can only be prepared at very high temperatures, particularly for ¹⁰Boron semiconductor compounds. However, in practice, the process of preparation of such large area epitaxial thick films is almost unmanageable.

Doty et al. describe [8] a neutron detector that relies upon single or polycrystalline, lithium tetraborate or alpha-barium borate compounds, useful for neutron detection. The crystals are prepared using known crystal growing techniques, wherein the process does not include the common practice of using a fluxing agent, such as sodium oxide or sodium fluoride, to reduce the melting temperature of the crystalline compound. Crystals prepared by this method could be sliced into thin single or polycrystalline wafers, or ground to a powder and prepared as a sintered compact. For this purpose the crystalline boule may be comminuted into a powder, mixed with any of a number of binders to aid in sintering, pressed into a ‘green’ shape and then sintered at a temperature of about 0.75-0.9 of the material melting temperature. The article may be configured with appropriate electronic hardware, in order to function as neutron detectors. It should be noted that although the utilizing of binders to aid in the sintering process was contemplated, Doty et al. do not expand on the nature and type of these binders.

In addition, according to Doty et al, the wafer also could comprise a screen printed layer of a paste formed by mixing a comminuted powder of the crystalline boule with any of a number of wetting and/or dispersing (suspension) agents. The printed layer would be placed onto an electrically conductive substrate acting as a charge collecting electrode. After drying the printed layer a second electrode would be placed onto the top surface of the layer.

Doty et al. also describes [10] a neutron detector that comprises a body of hexagonal boron nitride disposed between electrodes; power supply means for applying a voltage to the electrodes; and means for detecting and measuring the current pulse emitted from the hexagonal boron nitride. The voltage is applied in a direction substantially parallel to a crystallographic axis of the hexagonal boron nitride.

### SUMMARY OF THE INVENTION

There is a need in the art for, and it would be useful to have, a novel solid-form (bulk) semiconductor detector capable of passively detecting neutrons and alpha particles that can be readily adapted also for active use in neutron radiography and imaging techniques suitable for active imaging large objects.

The present invention satisfies the aforementioned need by providing a polycrystalline semiconductor (or semi-insulating) compound for use in a solid-state detector for detection of alpha particles and neutrons. The semiconductor compound comprises a powder of small grain size particles of sensitive particulate semiconductor material imbedded in a binder. The present invention provides several particular semiconductor materials and appropriate polymeric and/or inorganic binders which are mostly suitable for these semiconductor materials.

The present invention is further based on the realization that there exist specific semiconductor compounds, which in a particulate form, give especially advantageous detecting results.

The present invention is still further based on the realization that particulate semiconductor compounds embedded in specific organic binder materials, or specific inorganic binder materials give especially advantageous detecting results, as compared to semiconductor compounds in other binders.

The term “semiconductor compound”, as it appears in the present description and claims, refers to a semiconductor compound comprising the elements ⁶Li, ¹⁰B, ¹¹³Cd, ¹⁵⁷Gd or ¹⁹⁹Hg. Specific non-limiting examples of these compounds are B₄C, BN or BP as ¹⁰B carriers, LiF, LiNbO₃, Li₂B₂O₄ or Li₃PO₄ as ⁶Li carriers CdS, CdSe, CdTe, or CdZnTe-(CZT) as ¹¹³Cd carriers, and Gd₂S₃ as ¹⁵⁷Gd carriers and HgBrI or HgI₂ as ¹⁹⁹Hg carriers.

Preferably, in accordance with the invention, the compound is boron nitride (BN).

The semiconductor compound may be composed of the neutron sensitive isotopes, as they exist in nature or may be specially prepared with enriched isotopes of the neutron sensitive isotopes.

The term “small grain size particles” refers hereinafter to particles having a mean size in the range of 10 nm to 100 microns (μm), preferably in the range of 100 nm to 100 μm most preferably 500 nm to 50 μm.

The term “imbedded” herein refers to any sort of distribution of the powder in the binder, preferably a homogenous distribution. This term refers to both the imbedding during the course of preparation of the carrying matrix and the impregnation of the carrier matrix after it has been formed.

According to an embodiment of the present invention, the binder is an organic polymer binder comprising at least one polymer selected from the group comprising polystyrene, polypropylene, Humiseal™ (acrylic conformal coating) and polyamide 6 (i.e., Nylon-6).

According to another embodiment of the present invention, the binder is an inorganic binder selected from B₂O₃, PbO/B₂O₃₁, Bi₂O₃/PbO, Borax glass, Bismuth Borate glass and Boron Oxide based glass.

A ratio of the particulate semiconductor material to the dry binder can be generally in the range of 5:95 to 95:5 in weight %, and preferably in the range of 25:75 to 95:5 in weight %, depending on the mechanical strength of the finally dried, or flux sintered detector plate. For example, a ratio of the particulate semiconductor material to the binder can be in the range of about 50:50 in weight %. It should be noted that the more binder in the mixture, the higher is the mechanical strength but the fewer will be the amount of the semiconductors containing the nuclide with large cross section, to absorb and react with the neutrons. The liquid mixing medium, which can be toluene in the case of polymeric binder or water in the case of inorganic binder, is also of great importance, since the mixture of semiconductor and binder must have such viscosity so to allow the spreading of the mixture on the substrate. This liquid can be in the range of about 1 to 50%, and preferably about 5 to 15% of the total dry content.

In the case of mixing and melting the binder such as using nylon-6 or polypropylene, followed by hot pressing no liquid medium is necessary.

The present invention also provides a solid-state neutron detector having an active region formed of the polycrystalline semiconductor compound described above which is sandwiched between an electrode assembly configured to detect the neutron and alpha particles interacting with the bulk of said active region.

The electrode assembly comprises a continuous upper electrode, a bottom electrode associated with a detection pixilated substrate, and an electronic readout system coupled to the upper electrode and the bottom electrode. The detection pixilated substrate can be a focal pixel array constituted by an assembly of pixel elements comprising a set of stripe electrodes mounted on a top surface of a substrate containing readout electronic circuits used for analyzing detected signals. Specifically, each pixel element can be based on a readout electronic element selected from a Complementary Metal Oxide Semiconductor (C-MOS) chip, a charge coupled device (CCD) and Thin Film Transistor (TFT) electronics configured for obtaining an electrical charge generated in the active region.

According to an embodiment of the present invention, the continuous upper electrode of the detector can be made of at least one material selected from Aquadag and metals (e.g., gold, palladium, aluminum, copper, etc).

The present invention further provides an imaging system for imaging an object. The system comprises the solid-state neutron detector of the present invention placed in a location to allow the detector to intercept a stream of neutrons passing through said object. The imaging system also includes a processing system coupled to the detection pixilated substrate and adapted for reading the current, performing image processing and generating a signal indicative of said object; and an image display coupled to the processing system and configured for obtaining the signal, thereby displaying the object.

The detection pixilated substrate of the readout electronic circuits can, for example, include an array of square shaped pixels electrodes of about 30-1000 microns, or linear shaped electrodes having a width of 10-100 microns.

The present invention also satisfies the aforementioned need by providing a method of fabrication of the solid-state neutron detector of the present invention. The method comprises providing a polycrystalline semiconductor compound comprising a particulate semiconductor material of the present invention sensitive to neutron and alpha particles radiation imbedded in a binder. The method further includes attaching the polycrystalline semiconductor compound to a detection pixilated substrate constituted by an array of pixel elements; and depositing a continuous layer of conductive material on said bulk plate, thereby to form a continuous electrode of the detector.

According to the present invention, the step of providing the polycrystalline semiconductor compound comprises preparing polycrystalline semiconductor material sensitive to neutron and alpha particles radiation, providing the binder, and mixing the polycrystalline semiconductor particles with the binder.

Examples of the polycrystalline semiconductor material include, but are not limited to, BC, BN or BP as ¹⁰B carriers, LiF, LiNbO₃, Li₂B₂O₄ or Li₃PO₄ as ⁶Li carriers CdS, CdTe, or CdZnTe-(CZT) as ¹¹³Cd carriers, and Gd₂S₃ as ¹⁵⁷Gd carriers and HgBrI or HgI₂ as ¹⁹⁹Hg carriers.

The polycrystalline individual grains of all these semiconductors can be bound in an organic binder such as polymer, or in an inorganic insulator, or in a semiconducting glassy binder.

According to an embodiment of the present invention, the polycrystalline semiconductor compound can be prepared as slurry. More specifically, a powder of the polycrystalline semiconductor can be mixed with a polymeric binder, such as Humiseal™ or Polystyrene that can be mixed with a solvent such as toluene. In this case, the attaching of the slurry can be carried out by a coating method, such as Dr. Blade coating method, and/or any other method employing spreading or gluing the semiconductor/binder composite to the TFT multi-pixel or line electrode read out array or on the C-MOS multi-pixel or CCD multi-pixel or line electrode read out array, which is then dried to remove the organic solvent.

According to another embodiment of the present invention, the method of preparing the polycrystalline semiconductor compound can include: (i) mixing the semiconductor material with a polymeric binder, such as nylon-6 or polypropylene, (ii) extruding the mixture, and then (iii) hot pressing the extruded filaments to a detector plate. In this case, no organic solvent is required.

According to another embodiment of the present invention, the polycrystalline semiconductor compound can be prepared by mixing the semiconductor material with inorganic binder, and then sintering the mixture at relatively high temperature (about 70% of the melting point in ° K) in the shape of a bulk detector plate that can be glued on a large area substrate of imaging readout pixel elements to form the active region. In this case, the step of attaching of the plate can be carried out by gluing, for example, by a using a “flip-chip” technology.

According to an embodiment of the present invention, the neutron detector plate can be used in a neutron passive detector. To prepare such a detector, the neutron detector plate can be coated by opposite metal electrodes, attached to a high voltage bias system and connected to a known single photon nuclear spectroscopic counting system or current integrating system.

According to another embodiment of the present invention, the neutron detector plate can be used in a neutron active imaging system. In such a case, the neutron detector plate, already attached to the imaging device by its bottom pixel electrode coupled to imaging readout electronics, can be further coated with the uniform top electrode which can be done by painting a graphite paste such as Aquadag. Alternatively, providing of the upper electrode can be done by sputtering or evaporating the continuous metal electrode made of gold, copper, aluminum, palladium or chromium-nickel alloy, etc. At the top of the detector plate a metal wire can be attached with conductive glue and connected to a high voltage source.

The present invention also provides a method of detecting neutrons and alpha particles, the method comprising positioning the solid state neutron detector of the present invention in a location to allow the detector to intercept a stream of neutrons and/or alpha particles.

The detection process can be based on a nuclear reaction that takes place in the bulk of the semiconductor compound between the neutron and the nucleus of ¹⁰B or ⁶Li, which produces emission of alpha particles, or with ¹¹³Cd, ¹⁹⁹Hg and ¹⁵⁷Gd, which produces emission of gamma rays. The alpha or gamma radiation then ionizes the surrounding atoms and creates pairs of electrons and holes, which can be collected when an electric field is applied between the upper and bottom electrodes by applying high voltage thereacross. The neutron reaction process can take place within each portion of the detector operating as pixels of the imaging system. The charge from each pixel can be collected to form an image, whose resolution is determined by the size of the pixel.

It should be noted that the grain size of a granulated semiconducting material embedded in a binder is smaller or at least equal to the width of the stripe electrodes (size of the pixel element) of the detector.

The neutron detector of the present invention can be utilized for security and safety purposes to detect materials, which emit neutrons. Another application is neutron radiography imaging. Neutron diffraction and scattering analysis may also use this kind of detector.

Generally, the range of applicability of the neutron detector of the present invention includes: medical radiation dosimetry; detecting nuclear material; anti-terrorism and anti-smuggling devices; monitoring of nuclear reactors, of nuclear storage units and facilities, and of nuclear weapons, weapons storage and weapons shipment; life science materials and physical sciences scattering experiments; monitoring of neutron sources; calibration of neutron flux; personnel and environmental radiation protection; radiation protection at high energy radiation facilities; neutron cancer therapy; profiling of medical, therapeutic, research and other neutron beams; comet, planetary and other space exploration.

There has thus been outlined, rather broadly, the more important features of the invention so that the detailed description thereof that follows hereinafter may be better understood. Additional details and advantages of the invention will be set forth in the detailed description, and in part will be appreciated from the description, or may be learned by practice of the invention.

### BRIEF DESCRIPTION OF THE DRAWINGS

In order to understand the invention and to see how it may be carried out in practice, preferred embodiments will now be described, by way of non-limiting examples only, with reference to the accompanying drawings, in which:

FIG. 1 illustrates schematically a sectional view of a thin-film-coated semiconductor diode neutron detector;

FIG. 2 illustrates schematically a solid-form (or bulk) semiconductor diode neutron detector;

FIG. 3 is a schematic cross-sectional view of the neutron and alpha particles detector according to one embodiment of the present invention, which shows a basic structure thereof;

FIG. 4 illustrates a schematic view of an imaging system according to one embodiment of the present invention;

FIG. 5 illustrates an example of an Alpha-spectrum produced by 5.5. MeV alpha particles from ²⁴¹Am detected by a polycrystalline semiconductor detector based on the Polystyrene/BN compound, according to an embodiment of the invention;

FIG. 6 illustrates a dependence of the amplitude of the 5.55 MeV alpha-spectral photo peak from ²⁴¹Am as a function of the time measurement;

FIG. 7 illustrates a dependence of the amplitude of the 5.55 MeV alpha-spectral photo peak from ²⁴¹Am as a function of the amplitude of electric field;

FIG. 8 illustrates an example of 5.5 MeV Alpha-spectra from ²⁴¹ Am detected by another composite polycrystalline BN detector based on the Polystyrene/BN compound;

FIG. 9 illustrates an example of 5.5 MeV Alpha-spectra from ²⁴¹Am detected by still another composite polycrystalline BN detector based on the Polystyrene/BN compound;

FIG. 10 illustrates an example of 5.5 MeV Alpha-spectra from ²⁴¹ Am detected by still another composite polycrystalline BN detector based on the Polystyrene/BN compound;

FIG. 11 illustrates an example of 4.8 MeV Alpha-spectrum from ²²⁶Ra detected by a composite polycrystalline BN detector based on the Polystyrene/BN compound, according to an embodiment of the invention;

FIG. 12 shows an example of actual neutron spectrum emitted from ²⁴¹ Am—Be source taken by a composite polycrystalline BN detector based on the Polystyrene/BN compound, according to an embodiment of the invention;

FIGS. 13A and 13B show examples of the response of the detector obtained from the source of thermal neutrons and the response of the detector obtained without the source of thermal neutrons measured with two paraffin slabs for thermalizing neutrons, having different thickness;

FIGS. 14A and 14B show examples of the calculated Alpha-spectra of 1.47 MeV and 1.77 MeV alpha particles by subtracting the noise from the total number of counts resulting from the thermal neutrons of the source comprising ²⁵²Cf two paraffin slabs and a graphite slab for thermalizing neutrons.

FIG. 15 compares the Alpha-spectrum of 4.8 MeV alpha particles obtained from ²²⁶Ra source and the Alpha-spectrum of 1.47 MeV and 1.77 MeV alpha particles obtained from the source of thermal neutrons source comprising ²⁵²Cf and paraffin slab;

FIG. 16 shows exemplary responses to alpha radiation for a polycrystalline composite BN detectors based on the compound comprising BN particular material embedded in Nylon-6 matrix; and

FIG. 17 shows exemplary responses to alpha radiation for a polycrystalline composite Lithium fluoride LiF) detector.

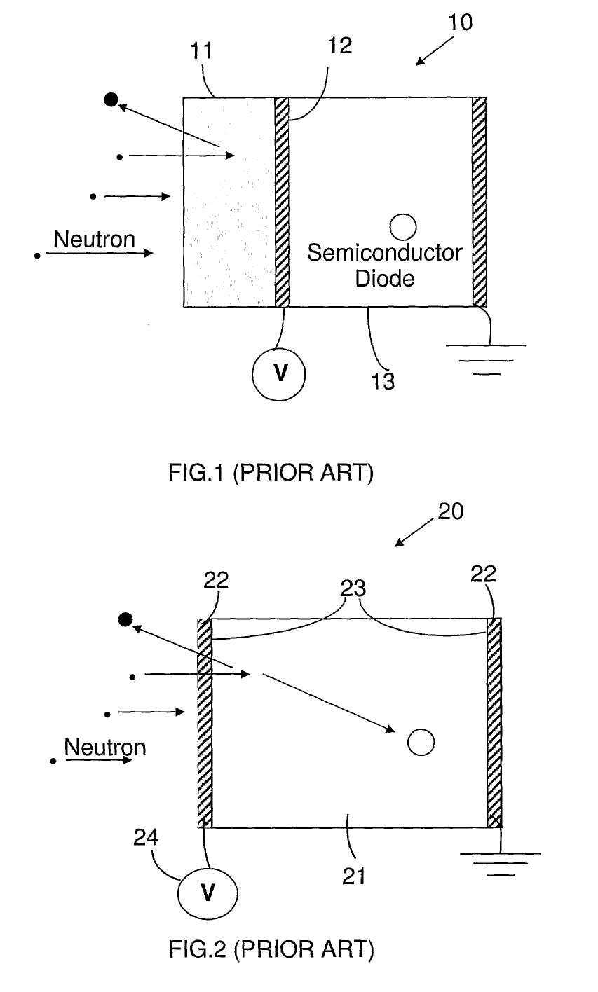

### DETAILED DESCRIPTION OF SPECIFIC EMBODIMENTS

The principles and operation of a detector for detection of alpha particles and neutrons according to the present invention may be better understood with reference to the drawings and the accompanying description. It should be understood that these drawings are given for illustrative purposes only and are not meant to be limiting. It should be noted that dimensions of layers and regions in the detector are not to scale, and are not in proportion, for purposes of clarity. It should be noted that the blocks as well other elements in these figures are intended as functional entities only, such that the functional relationships between the entities are shown, rather than any physical connections and/or physical relationships. The same reference numerals and alphabetic characters will be utilized for identifying those components which are common in the solid-state detector and imaging system shown in the drawings throughout the present description of the invention.

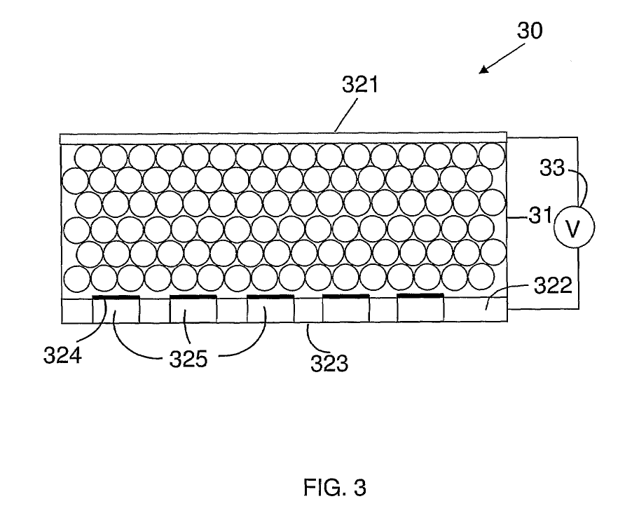

FIG. 3 illustrates a schematic view of a solid-state detector 30 for detection of alpha particles and neutrons, according to one embodiment of the invention. The solid-state detector 30 includes a detector plate 31 made of a polycrystalline semiconductor compound, prepared in accordance with the present invention, which is sandwiched between an electrode assembly configured to detect the neutron and alpha particles interacting with the bulk of the active region. The electrode assembly includes an upper electrode 321 and a bottom electrode 322 of the electronic readout system 32 of the detector 30. The upper electrode 321 and the bottom electrode 322 are coupled to a high voltage source 33. The detector plate 31 forms an active region of the detector 30. The upper electrode 321 is defined herein as the electrode where the alpha particle and/or neutron irradiation penetrates. The upper electrode 321 can be made, for example, of Aquadag, gold (Au), copper (Cu) and aluminum (Al), etc. Preferably, but not mandatory, the upper electrode 321 is a continuous electrode.

As shown in FIG. 3, the bottom electrode 322 is associated with a detection pixilated substrate 323 of the electronic readout system 32. The detection pixilated substrate 323 can be one- or two-dimensional focal pixel array constituted by an assembly of pixel elements. The detection pixilated substrate 323 can include an assembly of stripe electrodes 324, which are mounted on a top surface of a substrate containing readout electronic circuits 325 used for analyzing detected signals. Each pixel element can be based, for example, on a Complementary Metal Oxide Semiconductor (C-MOS) chip, a charge coupled device (CCD) or Thin Film Transistor (TFT) electronics, all configured for obtaining an electron/hole current generated in the active region.

For example, the detection pixilated substrate 323 can be an array of square shaped metallic strips of 30-1000 microns size or line array, with the strip width of 10-500 microns, which act as the bottom electrode of the detector plate 31 and associated with the readout electronic circuits 325. Such pixel arrays are commercially available, and come printed onto suitable substrates such as amorphous silicon, glasses and polymeric materials. A detector with the assembly (array) of readout pixel elements can form an imaging system.

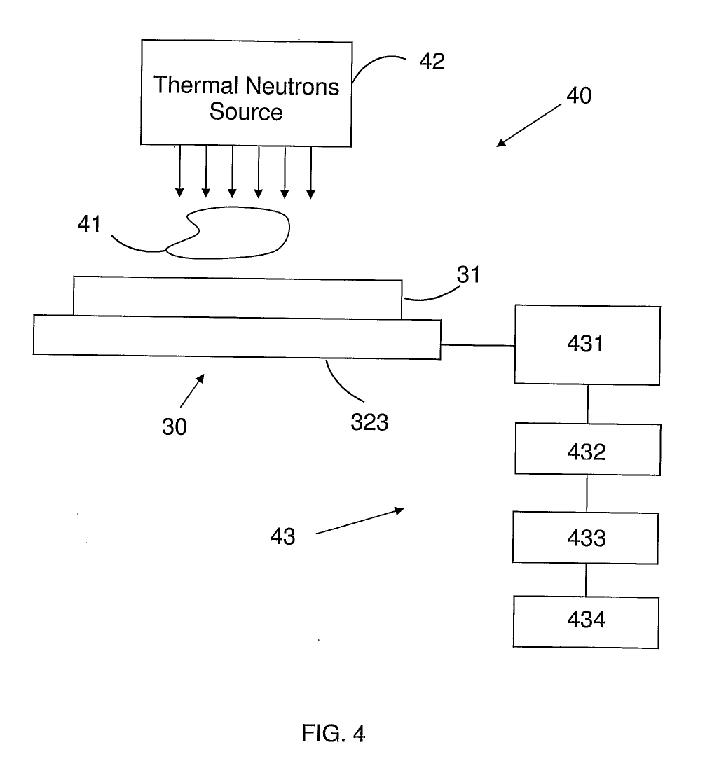

Referring to FIG. 4, there is schematically illustrated an exemplary imaging system 40 utilizing the solid-state detector 30 of the present invention configured for imaging an object 41 containing neutron sensitive elements, which is placed between a Thermal Neutron Source 42 and the solid-state detector 30. The detection pixilated substrate 323 includes pixel elements (not shown in FIG. 4) which are replicated to produce a complete two-dimensional image of the desired size. For example, the detection pixilated substrate 323 can include 1024 pixels by 1024 pixels of 127×127 micron each or any other size of the pixel dimensions, according to the desired resolution.

The imaging system 40 includes a processing system 43 coupled to the detection pixilated substrate 323 and adapted for reading the signal generated by the detection pixilated substrate 323 performing image processing and generating a signal indicative of said object.

The processing system 43 includes several known devices required for processing signals generated by the readout electronic circuits 431. For example, the imaging system 40 can include a pulse-shaping amplifier 431 to amplify and filter the signals. Thereafter the signal is fed to a multi-channel analyzer 432 which analyses the pulse height of each of the signal pulses received from the shaping amplifier 431, and then accumulates each of those digital signals in channel numbers corresponding to the magnitude of the signal. The signal spectrum output of multi-channel analyzer 432 is processed by a computer unit 433 and displayed on a display 434, or some other similar output device. The processing of the signal spectrum output according to the present invention is performed on the basis of an appropriate algorithm establishing a relationship between the signal output and an image of the object 41.

For large systems such as neutron imaging of large containers in large seaports, the Thermal Neutron Source 42 can be based on a specially built neutron reactor (not shown). However, for imaging small units, a radioactive source such as ²⁵¹Californium which emits neutrons or neutron generator (based on D-D or D-T reaction) can be used as a neutron source.

The polycrystalline semiconductor compound utilized in the detector 30 contains a particulate semiconductor material sensitive to neutron and alpha particles radiation imbedded in a binder. The particulate semiconductor material is in the form of a powder of small grain size particles. The small grain size particles can have a mean size in the range of 10 nm to 100 μm, preferably in the range of 100 nm to 100 μm, and more preferably 500 nm to 50 μm. It should be noted that the grain size of a granulated semiconductor material embedded in a binder is smaller or at least equal to the width of the stripe electrodes (size of the pixel element) of the detector.

The term “imbedded” herein refers to any sort of distribution of the powder in the binder, preferably a homogenous distribution. This term refers to both the imbedding during the course of preparation of the carrying matrix and the impregnation of the carrier matrix after it has been formed. According to the invention, the granulated semiconductor materials can be mixed with either an organic polymer binder, or an inorganic glassy binder.

The organic polymer binder can, for example, comprise at least one polymer selected from the group comprising aliphatic and aromatic homopolymers and copolymers. More specifically, examples of the polymeric binders suitable for the purpose of the present invention include, but are not limited to, polystyrene, polypropylene, Humiseal™ and Nylon-6.

In addition to organic polymer type binders, the present invention provides also polycrystalline ceramic binders to bind the semiconductor compound grains, and after sintering to form a detector plate. After deposition of conductive upper and bottom electrodes on the detector plate, it can be used in an alpha particles/neutron detector. An example of the inorganic binder includes, but is not limited to, B₂O₃, PbO/B₂O₃/, Bi₂O₃/PbO, Borax glass, Bismuth Borate glass and a Boron Oxide based glass.

According to the present invention, at least one of the components of the semiconductor material contains a neutron sensitive isotope, which can be either ¹⁰B or ⁶Li, which by the reaction with neutrons produce emission of alpha particles, or where at least one of the neutron sensitive isotope components of the semiconductor material is selected from ¹¹³Cd, ¹⁵⁷Gd, and ¹⁹⁹Hg, which by the reaction with neutrons produces emission of gamma rays.

The semiconductor material may be composed of the neutron sensitive isotopes, as they exist in nature or may be specially prepared with enriched isotopes of the neutron sensitive isotopes. It should be noted that all the above-mentioned isotopes with large cross sections for neutrons occur in the natural elements only in small concentrations of only 7.42% for ⁶Li, 19.78% for 10B, 12.26% for ¹¹³Cd, 15.68% for ¹⁵⁷Gd and 16.84% for ¹⁹⁹Hg. Therefore, in order to have maximum absorption of the thermal neutrons, the semiconductor compounds with enriched isotopes would preferably be used. Alternatively, it is also possible to use the natural materials with reduced concentration of the desired isotopes, but to use higher thicknesses of the semiconductor detector plate.

Specific non-limiting examples of these materials are BC, BP, BN, or BaB₂O₄ as ¹⁰B carriers; LiF, LiNbO₃, Li₂B₂O₄ or Li₃PO₄ as ⁶Li carriers; CdS, CdSe, CdTe, or CdZnTe-(CZT) as ¹¹³Cd carriers; Gd₂S₃ as ¹⁵⁷Gd carriers; and HgBrI or HgI₂ as ¹⁹⁹Hg carriers. The present invention provides several particular semiconductor materials and appropriate polymeric and/or inorganic binders which are mostly suitable for these semiconductor materials.

Preferably, in accordance with the invention, the compound is boron nitride (BN).

Moreover, it should be noted that in known neutron detectors LiF is used as a single crystal neutron scintillators, which means that the neutron radiation produces visible light which light in turn, indirectly, is electronically transformed into electrical charges. The inventors have shown for the first time that LiF can be used in a semiconductor neutron detector, which means that the neutron radiation produces directly, electrical charges.

Specifically, the feasibility of direct neutron detection based on semiconductor compound containing ¹⁰B has been proven by using a boron-carbide (B₅C) material [13]. However, there are a number of B-C solid solutions in the binary phase diagram B-C, and only the 84% (At) B is a material in the semiconducting phase. B₅C is p-type semiconductor with a reported band gap between 0.5 eV-1eV. Any deviation from this composition does not operate as a semiconductor, and therefore cannot be used for a solid-state neutron detector. The synthesis of B₅C is therefore difficult, and any contamination with free carbon will also increase its dark current. Thus, the reported boron-carbide (B₅C) neutron detector device [13] had to be prepared in a diode configuration.

Therefore, the use boron phosphide (BP) semiconductor compound would be advantageous over B₅C. BP has an indirect band gap of 2 eV, and direct band gap of 4.2 eV, which is larger than the gap for B₅C, thus allowing better room for temperature variations. The detector can thus be used in the metal-semiconductor-metal sandwich configuration, and not only in the diode configuration as the detector based on B₅C can be operated.

Moreover, it should be noted that boron nitride BN compounds can be chemically very stable and can be exposed to extremely high temperatures without any decomposition. BN has a cubic crystalline structure, which in itself is an advantage, having a better close packing and higher density similar to classical semiconductors such as Si or Ge.

An examples of other boron-based compound, which can be used for fabrication of alpha particles and neutron detectors, includes, but is not limited to, BaB₂O₄.

One example of the compound based on ⁶Li isotope, which is suitable for the purpose of the present invention, is LiNbO₃, which has a large band gap, and can also be used as a semi-insulating photoconductor material for detecting thermal neutrons. Other suitable compounds are based on ⁶Li are LiF, Li₂B₄O₇ and Li₃PO₄.

A material suitable for the semiconductor detectors of the present invention, which converts the thermal neutrons to gamma rays, can be also based on ¹¹³Cd, ¹⁵⁷Gd and ¹⁹⁹Hg isotopes. Examples of the Cd-based semiconductor compounds include, but are not limited to, CdS, CdSe, CdTe and Cd₁₋ₓZnₓTe (CZT). Examples of the Gd-based compounds include, but are not limited to, Gd₂O₃, Gd₂S₃ or GdF₃. Examples of Hg-based compounds include, but are not limited to, HgI₂ and HgBr₂₋ₓIₓ, where 2<x<1.5.

According to an embodiment of the invention, the granulated sensitive semiconductor compound can be sintered at relatively high temperature (about 70% of the melting point in ° K) in the shape of a detector plate that can be glued on a large area substrate of imaging readout pixel elements to form the active region.

According to another embodiment of the invention, for much lower temperature preparation of the detector, the semiconductor material can be used as small grains imbedded in a matrix, which serves as a binder composed of either an organic or inorganic material. It should be noted that in both cases it is possible, inter alia, to use binders containing ¹⁰B or ⁶Li, such as boron or lithium containing polymers and glasses, which can increase the ability to capture the thermal neutrons. In particular, the organic polymeric matrix can be prepared by one of the following: dissolving a polymer in a solvent, employing thermoplastic and using thermosetic polymeric preparation technique. All these methods are known per se, and therefore will not be expounded herein below.

It should be noted that the invented combination of the appropriate semiconductor materials and binders can result in enhanced detection counting efficiency and relatively low signal-to-noise ratio of the invented detector, when compared to prior art solid-form detectors. Moreover, when semiconductor compounds are fabricated with inorganic binders, the sintering process, according to the invention, can be carried out at relatively low temperatures (in the range of 500° C.-700° C.), when compared to prior art sintered compounds [8].

It should be also noted that using granulated semiconductors is less expensive than producing single crystals or depositing at very high temperatures epitaxial films. It should be appreciated that utilizing small particles of the granular semiconductor or semi-insulating materials (mixed with a polymeric organic binder or sintered with an inorganic glassy binder) enables fabrication of large area sensitive plates. The polymer or glassy binder binds all individual material grains together, thereby making it easier to fabricate a large area detector.

The fabrication of the detector can include either spreading the granular compound or gluing the composite mixture over a large area of the imaging readout electronics. It should be noted that such a technological operation is much less expensive than the procedure of high temperature chemical vapor deposition (CVD) used, for example, by Sane et al [11], which is also difficult and fails to produce required high crystalline quality. It would be easier and cheaper to prepare a large area-imaging detector by using polycrystalline grains, which are bonded together in a polymeric or inorganic binder, rather than to prepare large single crystal in bulk form, and then deposit the crystals as large area thick films.

According to an embodiment of the invention, the method of fabrication of a solid state detector for detection of alpha particles and neutrons generally includes providing a polycrystalline semiconductor compound comprising grains of alpha particles and neutron sensitive semiconductor materials imbedded in a binder. The method further includes attaching the polycrystalline semiconductor compound to a detection array constituted by an assembly of pixel elements of an electronic readout system; and depositing a continuous layer of conductive material on the bulk plate, thereby to form a continuous electrode of the electronic readout system.

According to the invention, the step of providing a polycrystalline semiconductor compound comprises preparing polycrystalline semiconductor granular particles of neutron sensitive elements, providing the binder, and mixing the polycrystalline semiconductor particles with the binder.

According to an embodiment of the invention, the polycrystalline semiconductor granular particles are based on the elements with large cross sections for neutrons such as ⁶Li, ¹⁰B, ¹¹³Cd ¹⁵⁷Gd and/or ¹⁹⁹Hg. Specifically, the synthesis of polycrystalline particles of Boron semiconductor material, such as BC, BP, BN, and/or BaB₂O₄, can be made by various known methods using natural isotopes of boron. For special applications and higher efficiencies, the natural boron should be replaced by enriched 10β isotope. In turn, polycrystalline granular particles of Li semiconductor material, such as LiF, LiNbO₃, Li₂B₄O₇ and/or Li₃PO₄, can be prepared with natural Li and for special cases and better sensitivity the natural isotope is replaced by ⁶Li. Particles of polycrystalline Cd materials, such as CdS, CdSe, CdTe and/or Cd₁₋ₓZnₓTe (CZT), can be prepared with natural Cd and for special cases and better sensitivity the natural isotope can be replaced by ¹¹³Cd-enriched isotopes. Particles of polycrystalline Gd materials, such as Gd₂O₃, Gd₂S₃ and/or GdF₃, can be prepared, whereas for special cases and better sensitivity, ¹⁵⁷Gd-enriched isotopes can replace the natural isotope. For polycrystalline Hg-based compounds, such as HgI₂ and/or HgBrI, for better sensitivity the enriched ¹⁹⁹Hg should be used.

According to the invention, the polycrystalline semiconductor particles (grains) can be mixed with either an organic polymer binder, or an inorganic glassy binder in various proportions.

A ratio of the particulate semiconductor material to the dry binder can be generally in the range of 5:95 to 95:5 in weight %, and preferably in the range of 25:75 to 95:5 in weight %, depending on the mechanical strength of the finally dried, or flux sintered detector plate. For example, a ratio of the particulate semiconductor material to the binder can be in the range of about 50:50 in weight %.

It should be noted that the more binder in the mixture, the higher is the mechanical strength but the fewer will be the amount of the semiconductors containing the nuclide with large cross section, to absorb and react with the neutrons. The liquid mixing medium, which can be toluene in the case of polymeric binder or water in the case of inorganic binder, is also of great importance, since the mixture of semiconductor and binder must have such viscosity so to allow the spreading of the mixture on the substrate. This liquid can be in the range of about 7 to 12% of the total dry content.

The organic polymer binder can, for example, comprise at least one polymer selected from the group comprising aliphatic and aromatic homopolymers and copolymers. More specifically, examples of the polymeric binders suitable for the purpose of the present invention include, but are not limited to, polystyrene, polypropylene, Humiseal™ (acrylic conformal coating) and polyamide 6 (Nylon-6).

Thus, the organic polymer binder is mixed with the semiconductor grains. Then, the slurry of the compound can be deposited on the detection pixilated substrate (323 in FIG. 3) by any known coating method, e.g., by the Dr. Blade coating method. Depending on the construction of the pixilated substrate, the slurry can be placed directly on the pixel elements, such as TFT multi-pixel, line electrode read out array, C-MOS multi-pixel or CCD multi-pixel, which is thereafter dried to remove the organic solvent.

According to another embodiment of the invention, the polycrystalline semiconductor compound can be prepared by mixing the semiconductor material with a polymeric binder (such as Nylon-6 or polypropylene), extruding the mixture, and then hot pressing the extruded filaments to a detector plate. In this case, no organic solvent is required.

In addition to organic polymer type binders, the present invention can also utilize polycrystalline ceramic binders to bind the semiconductor compound grains, and then to sinter the mixture in a desired shape, thereby forming a detector plate. After attaching the conductive upper and bottom electrodes to the detector plate by using, for example, a polymeric glue, it can be used in an alpha particles/neutron detector. An example of the inorganic binder includes, but is not limited to, low melting inorganic binder, such as Borax glass, Bismuth Borate glass and a Boron Oxide based glass.

An example of the inorganic binder includes, but is not limited to, a low melting inorganic binder, such as Borax glass, Bismuth Borate glass, a Boron Oxide based glass, etc. For example, the Boron Oxide based glass can be prepared as following: B₂O₃ and Bi₂O₃ powders are mixed in the molar ratio of 3:7 and sintered in a platinum crucible at temperature of about 800° C.-900° C. for one hour, and then quenched in water to prepare the glassy binder. The powdered binder is then wet pulverized in a ball mill or other grinding machine to a small size about 10 micrometers and then mixed, for example, with BN micro-crystals in a medium of propyl alcohol in the absence of air or water humidity. Then, the mixture is pressed into a pellet to the required shape and thickness (e.g., of about 0.1-5 mm), which is then directly glued with conductive glue bumps (for example, by using ‘flip-chip’ technology) on the readout electronic circuits. The substrate of the readout electronic circuits can, for example, be an array of square shaped pixels electrodes of about 30-1000 microns, or linear shaped electrodes having a width of 10-500 microns, which are associated with TFT, C-MOS or CCD chips.

The detector plate (31 in FIG. 3), glued to the bottom electrode 322 that is associated with a detection pixilated substrate (323 in FIG. 3), can be further coated with the uniform upper electrode (321 in FIG. 3). The forming of the upper electrode 321 can, for example, be performed by painting a graphite paste (e.g., Aquadag). Alternatively, the forming of the upper electrode can be performed by sputtering a continuous metal electrode of either gold, palladium or chromium-nickel alloy. Then, at the top of the detector plate, a metal wire having a diameter, for example, of about 50 microns can be attached with conductive glue for connecting to a high voltage source (not shown in FIG. 3), hereby preparing the detector for imaging.

According to a further embodiment of the invention, the method of fabrication of the solid state detector can include encapsulating the detector plate by covering it with a polymer (such as, Parylene, Humiseal, etc) to protect it from environment, while leaving free the metallic connection pads for connection to the read-out imaging electronics.

### EXAMPLES

The essence of the present invention can be better understood from the following non-limiting examples of preparation of various semiconductor compounds, which are intended to illustrate the present invention and to teach a person of the art how to make and use the invention. These examples are not intended to limit the scope of the invention or its protection in any way.

### Example 1

In order to synthesize boron phosphide (BP) material, PCl₃ in the amount of 4 ml, NaBF₄ in the amount of 5.3 g and metal Na in the amount of 7 g were placed in a stainless steel autoclave having capacity of 50 ml under protective atmosphere of N₂. After sealing, the autoclave was heated at 400° C. for 6 hours and then cooled to room temperature. The precipitates were washed with absolute alcohol, HCl and distilled water, consequently, to remove the formed NaCl and NaF. Then the precipitates were dried in vacuum at 60° C., to yield black micro-grains of BP having mean dimension of about 1 micrometer size.

The formed grains of BP were mixed with polystyrene and toluene in the proportion of 80 wt % of BP and 20 wt % polystyrene and toluene to form a gelatinous paste. This paste was then glued with a Dr Blade coating method onto a C-MOS read out chip of 2 cm×2 cm containing 100×100 micrometer sized pixel electrodes with a pitch of 20 micrometers and a thickness of 100 μm, and dried at room temperature in a vacuum furnace. The chip was then connected to read out electronics, to be ready for neutron imaging.

### Example 2

For preparation of BP, first, a boron phosphide material was synthesized as in Example 1. Then, the micro-crystals were mixed with an inorganic Boron/Bismuth Oxide based glass. In order to prepare the glass binder, B₂O₃ and Bi₂O₃ powders were mixed in the molar ratio of 3:7 in a platinum crucible, and then subjected to temperature of 900° C. for one hour, and thereafter quenched in water. The powder is then wet pulverized in a ball mill or other grinding machine to grains having small size of about 10 micrometers, and then mixed with the BN micro-crystals in a medium of propyl alcohol in the absence of air or water humidity. Finally, the compound was pressed into a pellet and glued with Humiseal™ to a C-MOS chip, as described in Example 1.

### Example 3

Analytical-grade tertiary calcium phosphate (Ca₃(PO₄)₂) and ammonium biborate hydrate (NH₄HB₄O₇.3H₂O) were selected as starting materials where calcium phosphate was used as a diluting agent to prevent the formation of bulk B₂O₃ during the thermolysis of biborate hydrate. In a typical experimental procedure, Ca₃(PO₄)₂ powder in the amount of 10 g was dispersed into anhydrous ethanol (C2H5OH) in the amount of 400 mL, and then ball-milled for 8 hours to obtain Ca₃(PO₄)₂ suspension.

Ammonium biborate saturated aqueous solution that contains 10 g of NH₄HB₄O₇.3H₂O was dripped into the vigorously stirred Ca₃(PO₄)₂ anhydrous ethanol suspension at room temperature. Ammonium biborate hydrate was deposited on the surface of Ca₃(PO₄)₂ particles owing to its insolubility in the anhydrous ethanol. After the separation from the mother solution, Ca₃(PO₄)₂—NH₄HB₄O₇ composites were washed by anhydrous ethanol and dried at room temperature.

Finally, NH₄HB₄O₇ coated Ca₃(O₄)₂ powder was put into quartz crucible where it was nitrided at 900° C. for 8 hours to obtain Ca₃(PO₄)₂—BN composites in the flow of NH₃ gas, using a tube furnace. The flow rate of NH₃ gas was 1000 mL/min. The samples were removed from the tube furnace after cooling to room temperature in the flow of NH₃ gas and then treated using 6M of HCl aqueous solutions. Ca₃(PO₄)₂ reacts with HCl and dissolves in HCl aqueous solution. The residual white powders are BN powders. After filtration, the as-prepared BN powders were washed three to five times with anhydrous ethanol, then dried at 120° C. for 8 hours, and finally crystallized at different temperatures for 2 hours in N gas. The BN thus obtained was mixed with a polymeric binder, and a detector plate was produced, as in Example 1.

### Example 4

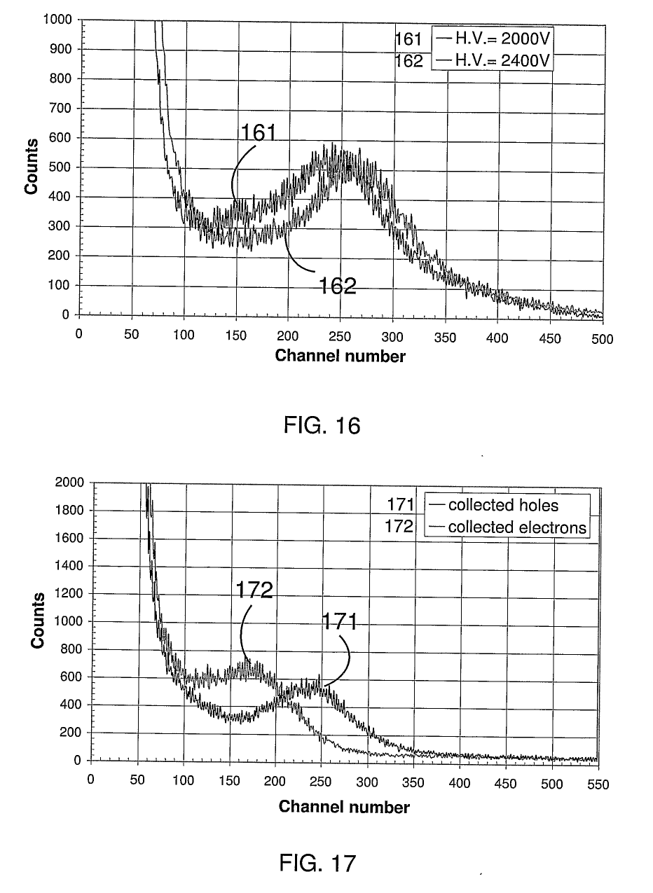

Melt-mixed polymer blends were composed of nylon 6 pellets and boron nitride powder. Melt blending was done by using Nylon 6 with 50 wt % Boron Nitride powder and carried out in a Micro 15 twin-screw compounder (DSM, Netherlands). Blending was performed at 240° C. for a period of 15 minutes with the screw speed of 100 rpm. That was followed by the extrusion at this temperature of spaghetti-like filaments. The resulting blends were pressed (by using Carver Laboratory press Model 2518) under pressure of 2 MPa and at a temperature of 210° C. in a mold to produce 0.7 mm thick films. The BN plate thus obtained was glued with poliol to a C-MOS chip, as described in Example 1. The Alpha spectrum obtained by employing this compound is shown hereinbelow with reference to FIG. 16.

### Example 5

Melt-mixed polymer blends were composed of Ziegler-Natta isotactic polypropylene (iPP, having a weight average molecular weight, Mw, of 135,000 g/mol, Capilene U77, Carmel Olefins, Israel) and boron nitride powder. Melt blending of iPP with 80 wt % Boron Nitride powder was carried out in a Micro 15 twin-screw compounder (DSM, Netherlands). Blending was performed at 240° C. for a period of 15 minutes with the screw speed of 100 rpm. The blending was followed by the extrusion at this temperature of spaghetti-like filaments. The resulting blends were pressed (Carver Laboratory press Model 2518) under pressure of 2 MPa and at a temperature of 210° C. in a mold to produce 0.7 mm thick films and glued with poliol to a C-MOS chip, as described in Example 1.

### Example 6

BN was produced as in Example 3 but is mixed with an inorganic binder and a detector plate was produced as described in Example 2.

### Example 7

Commercially available analytical grade LiF was mixed with polystyrene, as shown in Example 1. A detector plate was produced as described in Example 1. After depositing Aquadag (as the upper electrode) and Al foil (as the bottom electrode), the detector was biased at 600 volts and irradiated with 5.5Mev alpha radiation from a ²⁴¹Am source. The spectrum is shown is shown herein below with reference to FIG. 17.

### Example 8

Cd_{0.8} ZnO₂ Te powders were mixed with a polymeric binder and a detector plate was produced as in Example 1.

### Example 9

Cd_{0.8} Zn_{0.2} Te powders were mixed with a boron oxide glassy binder and a detector plate was produced as in Example 2.

### Example 10

Gd₂O₃ powders were mixed with a polymeric binder and a detector plate was produced as in Example 1.

### Example 11

Gd₂O₃ powders were mixed with a boron oxide glassy binder and a detector plate was produced as in Example 2.

### Example 12

HgBr_{0.5}I_{1.5} powders were mixed with a polymeric binder and a detector plate is produced as in Example 1.

### Example 13

HgBr_{0.5}I_{1.5} powders were mixed with a boron oxide glassy binder and a detector plate was produced as in Example 2.

### Example 14

HgI₂ powders were mixed with a polymeric binder and a detector plate was produced as in Example 1.

### Example 15

HgI₂ powders were mixed with a boron oxide glass based binder and a detector plate was produced as in Example 2.

### Example 16

First, a solution of polystyrene in toluene was prepared. For this purpose, 9 grams of Toluene were added to 2 grams of solid pieces of polystyrene. The mixture was closed in a hermetically sealed glass vessel. Then, the polystyrene was dissolved by heating to 60° C. and was continually stirred with a magnetic stirrer. When the solid pieces of polystyrene were fully dissolved, the mixture was cooled down to room temperature.

In order to prepare a polycrystalline semiconductor compound, a powder (grain size of about 1 micron) of BN in the amount of 0.75 g was added to small glass vessel together with the polystyrene in toluene solution in the amount of 0.1 g. The powder was mixed in the polystyrene in toluene solution by vibrating until homogenous slurry was achieved.

Thereafter, the slurry of BN particles mixed with polystyrene in Toluene solution was taken by a spatula and pasted on a conductive substrate (e.g., Indium Tin Oxide (ITO) glass substrate) to form a smooth, uniform film. The covered conductive substrate was left to dry in the room temperature for 12 hours, thereby forming a detector plate.

Thereafter, an upper electrode having an area of about 2 mm² was placed by painting the detector plate with Aquadag (graphite suspension). Finally, one metal wire (e.g., made of Cu) was attached to the electrode, whereas another metal wire was attached to the conductive substrate, thereby forming terminals.

Examples of the response to alpha radiation of four polycrystalline composite BN detectors based on the BN-in-Polystyrene compound (referred as Detectors 14) will be described hereinbelow.

The Detector 1 is 0.45 mm thick and has an area of 3 mm². The upper contact electrode is formed of Aquadag, whereas the bottom electrode is formed of ITO.

The Detector 2 is 0.80 mm thick and has two electrical contact areas of 3 mm² and 50 mm², where both areas were irradiated with alpha via a collimator of 6 mm diameter, at a distance of 6 mm, between the alpha source and the upper contact electrode of the detector. The upper contact electrode is formed of Aquadag, whereas the bottom electrode is formed of Al foil.

The Detector 3 is 0.80 mm thick and has an area of 20 mm². The upper contact electrode is formed of Aquadag, whereas the bottom electrode is formed of Cu foil. The Detector 4 is 0.90 mm thick and has an area of 6 mm². The upper contact electrode is formed of Aquadag, whereas the bottom electrode is formed of Al foil.

The Alpha radiation counting is similar to that which can be obtained by the nuclear reactions of ₅¹⁰B+₀¹n→₂⁴He+₃⁷Li (₂⁴He equal to Alpha radiation) mentioned above.

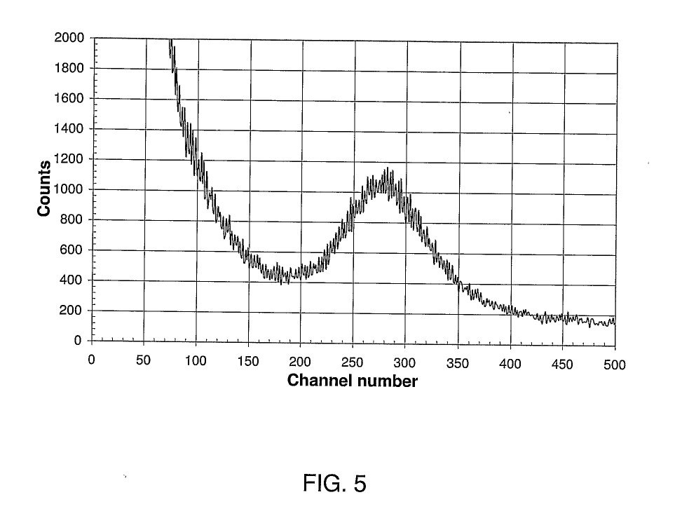

FIG. 5 shows an exemplary spectrum of the 5.5 MeV alpha from ²⁴¹Am source detected by the Detector 1 based on the BN/Polystyrene compound. The high voltage bias applied across the electrodes was 1600V. Since BN is a semiconductor where major carriers are holes, the negative polarity was applied on the bottom contact, for collection of holes. The amplification was about 400,000 (K_{preamplifier}˜1,000×K_{amplifier spectroscopy}=400). The range of 0-500 channels that corresponds to 0-5V have been considered. A diameter of a collimator was 3 mm, whereas the distance from the collimator to the upper contact was 6 mm. The time of measurement was 50 min. As can be seen in FIG. 5, the peak corresponding to 5.5 MeV alpha particles is centered on the 270 energy channel.

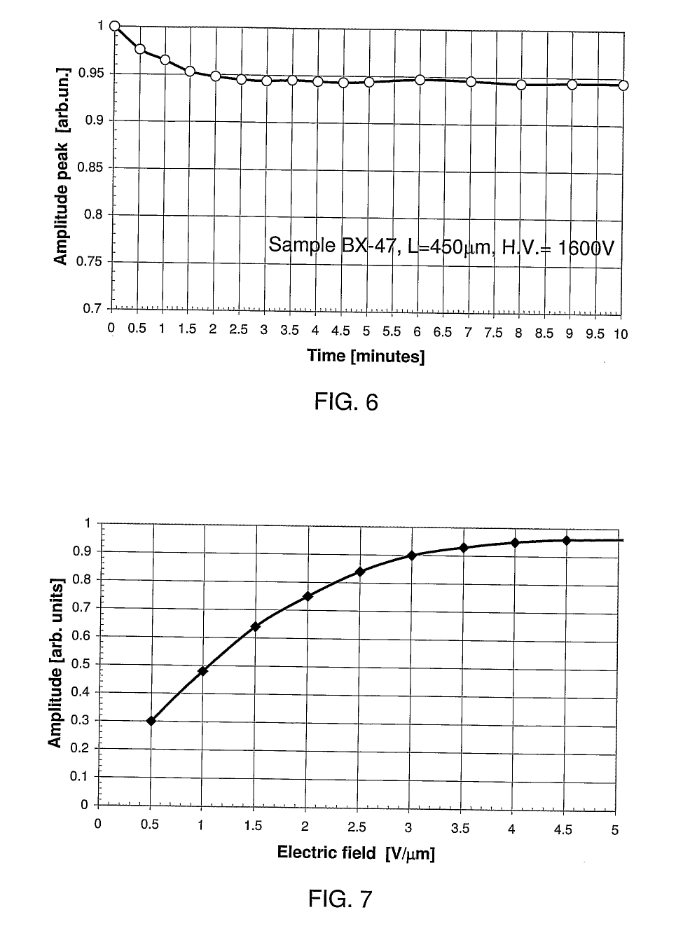

FIG. 6 illustrates a dependence of the amplitude of the 5.5 MeV alpha-spectral peak from ²⁴¹Am as a function of the time measurement. It can be seen that for Alpha collection there is a very weak polarization, which is expressed as the reduction of the amplitude of the alpha peak from the start of irradiation over time. Specifically, the amplitude of the alpha peak is reduced from 100% to only 95% from its original value over 2 min from the start of irradiation.

FIG. 7 shows data for the total number of counts measured on detector 1 as a function of the bias electric field (i.e., voltage applied across the electrodes per number of microns of thickness). As can be understood, the bias electric field used for the alpha detection was 4V/micron of thickness of the detector, where 95% of the total number of counts was obtained. However even with 1.5 V/micron field one can obtain 65% of the counts.

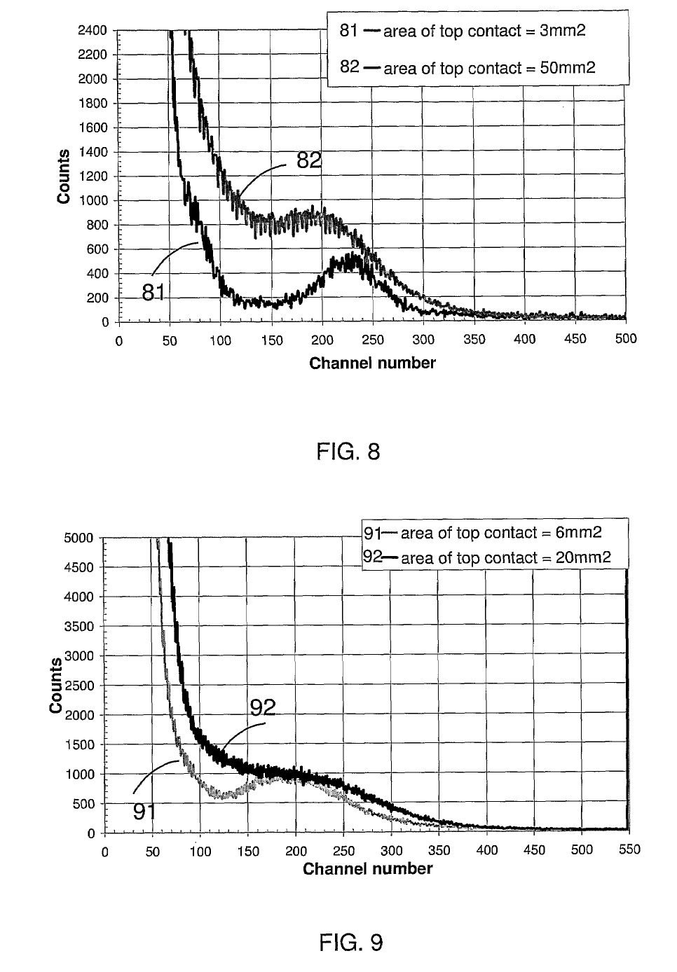

Referring to FIG. 8, in order to check the influence of the size of the irradiated area on the alpha spectrum, a response of the detector 2 was checked. The results of measurements alpha spectra are shown for the two cases when the area of the upper electrode was set to 3 mm² and 50 mm² (see curves 81 and 82, respectively). The thickness of the detector plate was 0.80 mm for both cases. The bias voltage was 2000V and in both cases, and the Alpha radiation was collimated by a collimator having a diameter of 6 mm with the distance from the Alpha source to the upper Aquadag electrode of 6 mm.

By comparing results shown in FIG. 5 and FIG. 8 for the 3 mm² area, one can see that the alpha-peak shifts from channel 270 (the 0.45 mm detector) to 230 (the 0.80 mm detector), due to the lower electric field in the thinner detector, which is 2000V/800 micron=2.50 in the 0.45 mm detector whereas 1600V/450 micron=3.55 V/micron in the 0.80 mm detector.

As shown in FIG. 8, the larger area detector which irradiates an area of 50 mm² has the alpha peak shifted to even lower channel of 170, due also to the larger capacitance noise caused by the ratio of the area of 50/3≈17, which is about 17 times larger for the larger area detector. But the integrated number of counts is also increased by more than one order of magnitude from 23,723 counts in the small area detector of 3 mm² to 2246,250 counts in the 50 mm², as counted between channels 60 to 550.

FIG. 9 illustrates an example of 5.5 MeV Alpha-spectra from ²⁴¹Am detected by the Detector 3. The thickness of the detection plate of the Detector 3 has the magnitude of 0.8 mm. Two cases with the Aquadag upper electrode with areas of 6 mm² and 20 mm² have been considered. From FIG. 9, one can see the difference between the large and small area detector. A curve 91 corresponds to the Alpha-spectrum for the case when the upper electrode area is 6 mm², whereas a curve 92 corresponds to the Alpha-spectrum for the case when the upper electrode area is 20 mm². In both cases the beam of Alpha particles was collimated by a collimator having a diameter of 6 mm and the distance from the ²⁴¹ Am source to the upper Aquadag electrode was 6 mm. The upper electrode is formed of Aquadag whereas the bottom electrode is a foil of Cu, with a total area of about 1.5 cm with negative polarity of the bias voltage on the Cu foil.

The range of 0-500 channels was considered (that is equal to 0-5V). One can see that similar to the results shown for Detector 2 (see FIG. 8), the Detector 3 with the larger area (20 mm² detector) has a much wider spread of the alpha spectrum than the spectrum spread of the smaller area detector (6 mm² detector). Accordingly, the number of counts for the 6 mm² detector is 294,967 counts, whereas the number of counts for the 20 mm² detector is 525,536 counts. Similar to the case of Detector 2, the number of counts is not linearly dependent on the size of the area, due to the geometrical differences between the angles in each case of the radiation with the collimator.

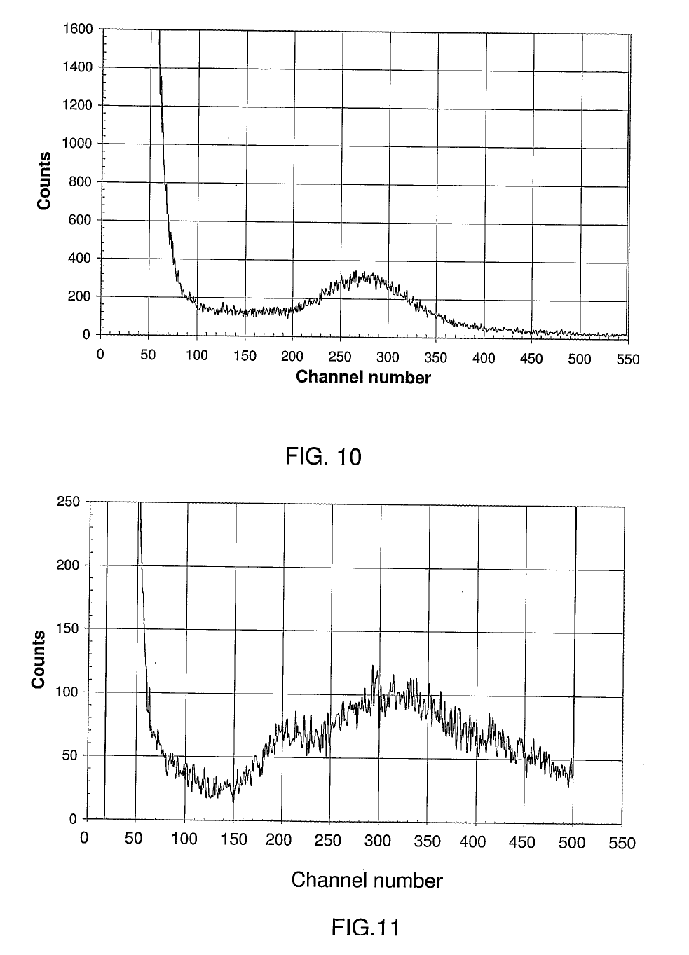

FIG. 10 illustrates an example of 5.5 MeV Alpha-spectra from ²⁴¹Am detected by the Detector 4. This detector was 0.9 mm thick, the upper electrode was formed of Aquadag with the area of 6 mm², whereas the bottom electrode was formed of aluminium. The bias high voltage was 2400V. The polarity of the high voltage was negative on the bottom electrode.

The Detector 4 was also used for measurements of alpha particles emitted from ²²⁶Ra (4.8 MeV) with the same bias voltage 2400V.

FIG. 11 illustrates an example of 4.8 MeV Alpha-spectrum from ²²⁶Ra detected by the Detector 4. As can be seen the Alpha-spectrum includes a major peak and another weak peak. For the ²²⁶, the main alpha peak of the 94.5% of the 4.77 .Mev is centered at the channel 310, whereas the 5% remaining weaker alpha peak of 4.6 MeV could be centered at channel 220. In such a case, the BN detector can differentiate between the two alpha peaks. A total number of counts of 51,175 were measured 100 sec between channels 50 and 550.

The Detectors 3 and 4 were also tested for neutron detection. The thermal neutrons were received from a very weak source comprising ²⁴¹Am—Be material followed by a paraffin slab having thickness of 8 cm. The neutrons were received according to the reaction ₂⁴He+94Be→₆¹²C+₀¹n, where ₂⁴He is the 5.5 MeV alphaparticle emitted from ²⁴¹Am which owing to the reaction with ₄²Be yields about 70 neutrons per one million alpha particles.

A much stronger source of neutrons was also used, comprising ²⁵²Cf material followed by a paraffin slab having thickness of 10 cm, which emits neutrons by spontaneous fission, at energies of 0.2-10 MeV with a maximum in the range of about 0.5 MeV-1 MeV. As noted, the neutrons were thermalized by paraffin slabs.

The distance between the thermal neutrons and the Detector 3 was in the range of 8.5 cm-0.5 cm, the amplification was about 400,000 (K_{preamplifier}˜1,000×K_{amplifier spectroscopy}=400), the measurement time was 6400 sec. No collimator was used. The thickness of the detection plate was 800 microns; the area of the Aquadag upper electrode was set to 20 mm². The bias voltage applied across the electrodes was 1500V. Thus, the electric field was 1.875V/micron, which according to FIG. 7 gives about 72% of the total number of alpha counts.

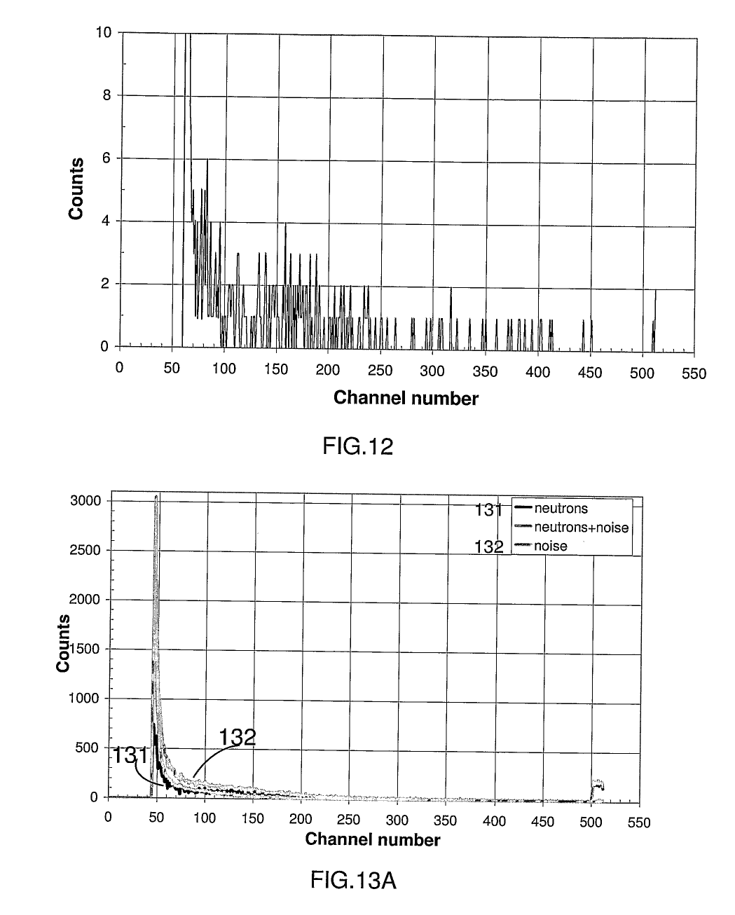

FIG. 12 shows an example of actual neutron spectrum emitted from ²⁴¹Am—Be source taken by the Detector 3. The spectrum has an apparent peak around the 150 energy channel. The range 0-500 channels correspond to 0-5V. The total number of neutrons counted in two hours was 302, as counted between channels 62-550.

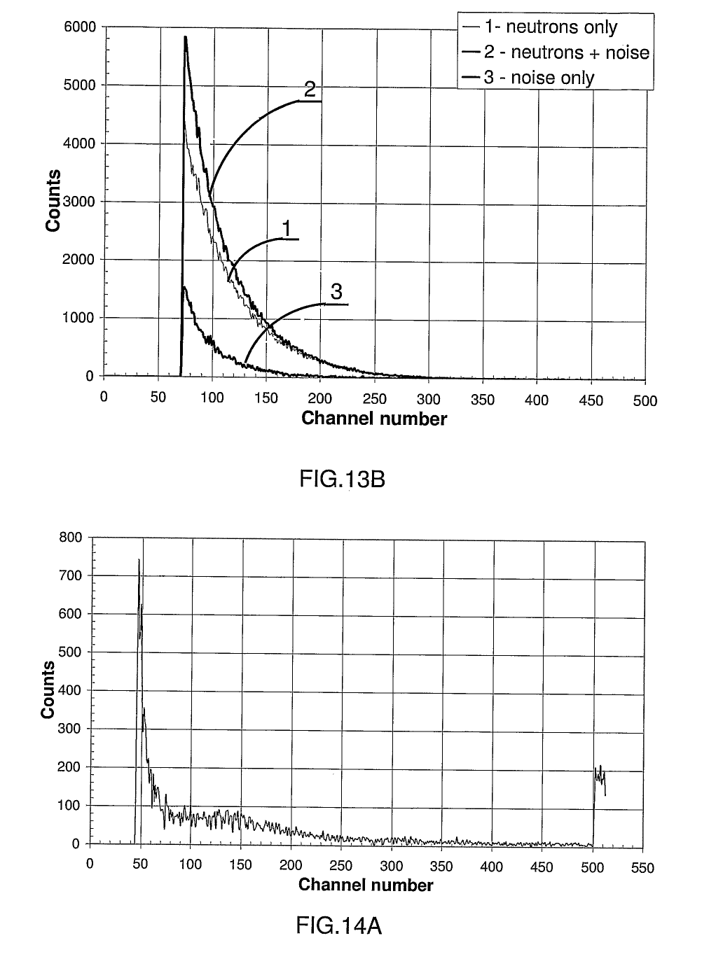

The thermal neutrons, emitted from a source comprising ²⁵²Cf material followed by a paraffin slab having thickness of 10 cm, were measured by the Detector 4 in which alpha particles of 1.77 Mev and 1.47 MeV were produced, owing to the nuclear reaction of the neutrons with the ¹⁰B in BN. FIG. 13A shows an example of a response 131 of the detector 3 obtained from the source of thermal neutrons and a response 132 of the detector obtained without the source of thermal neutrons. The bias voltage across the upper and bottom electrodes was 2100 V. The time of measurement was 2 hours. The distance between the neutron source and the detector was 6 meters. The total number of counts taken from this source of neutrons was 42427. The intensity of the neutron source together with noise was 11.8 pulses/sec. The total number of counts of noise (without the neutron source) was 20922. The intensity of only the noise (without the neutron source) was 5.8 pulses/sec.

FIG. 13B shows an example of a response of a detector 3 measured with a thicker paraffin slab and a graphite slab for thermalizing neutrons. It can be seen that the measured data have better statistics than those shown in FIG. 13A. Initial spectra of the alpha particles produced by the thermal-neutrons were measured over 6000 sec, producing a total number of counts for neutrons and noise of 243074 counts. The total number of counts of the noise only in the absence of the neutron source was 44238 counts, yielding a signal-to-noise ration 18.2. The total number of counts of expressed as the intensity of (neutrons+noise) was 40.5 pulses/sec, whereas the intensity of the noise only was about 7.4 pulses/sec. The higher count rate of the ²⁵²Cf source was obtained in the case of a thicker thermalizing slab inserted between the neutron source and the composite BN detector.

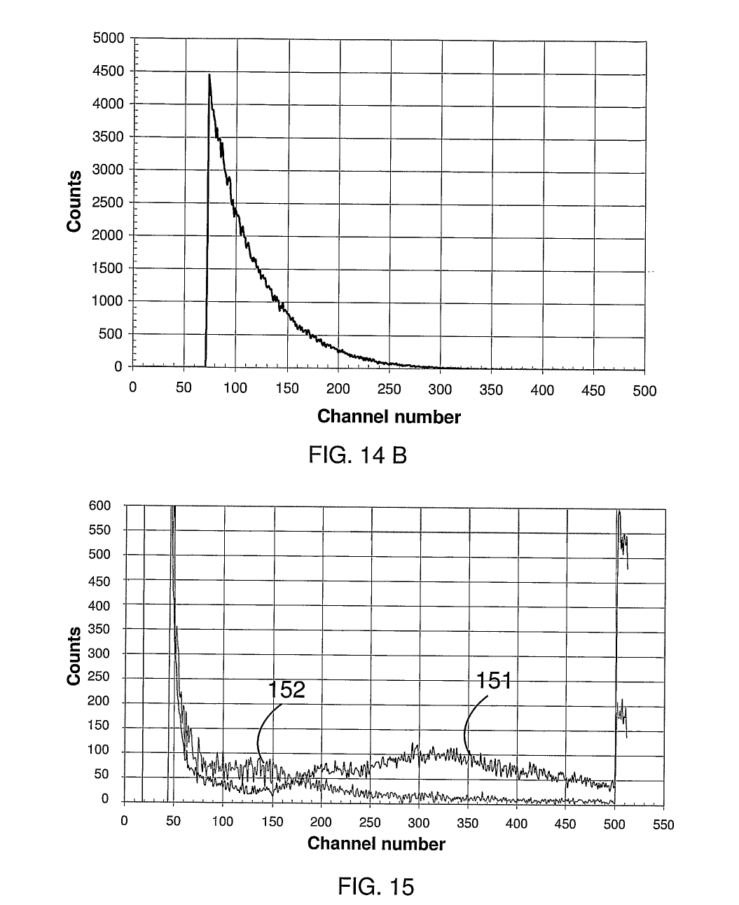

FIG. 14A shows an example of the calculated Alpha-spectra of 1.47 MeV and 1.77 MeV alpha particles resulting from the thermal neutrons of the abovementioned source comprising ²⁵²Cf and paraffin slab, from which the counts of noise are subtracted from the total number of counts, shown in FIG. 13a. The intensity of signals from the thermal neutrons was 6 pulses/sec. The amplitude of the peak is observed in the channel 140. It should be noted that the amplitude of the peak originated from 4.8 MeV alpha particles from the ²²⁶Ra source is 2.2 times lower (see FIG. 11).

FIG. 14B shows the net calculated alpha particles spectrum from the ²⁵²Cf thermal-neutrons, taken by subtracting the total number of counts of the electronic noise from the total number of counts taken in the presence of neutron source and noise (shown in FIG. 14A). The time of measurement was 6000 sec, the total number of counts was 198836 neutrons, corresponding to an intensity of about 33 pulses/sec.

FIG. 15 compares the Alpha-spectrum (curve 151) of 4.8 MeV alpha particles obtained from ²²⁶Ra source (taken from FIG. 11) and the Alpha-spectrum (curve 152) of 1.47 MeV and 1.77 MeV alpha particles obtained from the source of thermal neutrons source comprising ²⁵²Cf and paraffin slab (taken from FIG. 14a). Thus, the detector is sensitive for detection of the spectra for the 4.6 MeV particles as well as for the lower energetic particles (1.47 MeV and 1.77 MeV). The peaks are not buried in the noise range.

Referring to FIG. 16, exemplary responses to alpha radiation are shown for a polycrystalline composite BN detector based on the compound comprising BN particular material embedded in Nylon-6 matrix. The compound was prepared as described in Example 4, thereby forming a detector plate with the thickness of 600 micrometers. After cleaning the top and bottom surfaces of the detection plate from oxide, upper and bottom electrodes were placed by painting the detector plate with Aquadag. The contact area of the upper electrode was about 4 mm², whereas the contact area of the bottom electrode was about 20 mm².

The negative polarity was applied on the bottom contact for collection of holes. The bias high voltage was 2000V and 2400V (see curves 161 and 162, respectively). The amplification was about 400,000 (K_{preamplifier}˜1,000×K_{amplifier spectroscopy}=400). The range of 0-500 channels that corresponds to 0-5V have been considered. The diameter of a collimator was 3 mm, and the distance from the collimator to the upper contact was 6 mm. As can be seen in FIG. 16, the 5.5 MeV alpha peaks are in the range of the 250 to 270 energy channels when the bias high voltage has the values of 2000V and 2400V, respectively.

Referring to FIG. 17, exemplary responses to alpha radiation are shown for a polycrystalline composite Lithium fluoride (LiF) detector based on the compound comprising LiF particular material embedded in polystyrene matrix. The compound was prepared by mixing a powder of LiF (grain size of about 5 micron) together with polystyrene and toluene as shown in example 6. Then the mixture was heated at 40° C. over 12 hours thereby forming a detector plate with the thickness of 380 micrometers. After cleaning the top and bottom surfaces of the detection plate from oxide, upper and bottom electrodes were placed by painting the detector plate with Aquadag for the upper electrode. The contact area of the upper electrode was about 4 mm², whereas the contact area of the bottom electrode was about 20 mm². The bottom electrode was about 1.5 cm² and formed of an Al foil.

Alternatively, the negative polarity, and thereafter the positive polarity were applied on the bottom contact for collection of holes and electrons, (see curves 171 and 172, respectively). The bias high voltage was 600V. The amplification was about 400,000 (K_{preamplifier}˜1,000×K_{amplifier spectroscopy}=400). The range of 0-550 channels that corresponds to about 0-5.5V have been considered. The diameter of a collimator was 3 mm, and the distance from the collimator to the upper contact was 6 mm. As can be seen in FIG. 17, the 5.5 MeV alpha peaks are in the range of the 220-250 energy channels for the collected holes and in the range of the 220-250 energy channels for the collected electrons, respectively.

In summary, it should be noted that the described results of detection experiments of alpha particles show that all detectors tested regardless of the binder show a photo peak around the 250-270 energy channels for collecting holes. There was very little polarization of the alpha radiation, since the amplitude of the alpha photo peak is reduced from 100% to 95% over 2 min from the beginning of irradiation. The amplitude is maintained stable at this level for a further 10 minutes. In turn, neutron detection showed an apparent peak around the 150 energy channel. Although the signal-to-noise ratio for neutron detection was only 2, the 1.47 MeV and 1.77 MeV alpha peaks (resulting from the nuclear reaction of the neutrons emitted from the source based on 252-Californium with 10-Boron of the boron nitride detector) are not buried in the noise range.

For spectroscopic detection, the capacitance noise requires small contact areas, each of about 10 mm². Therefore, for large area spectroscopic detectors it is necessary to produce an electronic read-out device which can add up a multitude of such 10 mm² pixilated contacts. However for counting only, larger area detectors can be produced and detected in a spectroscopic system, if viewed via a small sized collimator placed at a given geometrical distance between the detector contact area and the thermal neutrons source. If an alpha source is collimated and radiated even over a 50 mm² area, the counting efficiency is much improved.

As such, those skilled in the art to which the present invention pertains, can appreciate that while the present invention has been described in terms of preferred embodiments, the concept upon which this disclosure is based may readily be utilized as a basis for the designing of other structures, systems and processes for carrying out the several purposes of the present invention.

Also, it is to be understood that the phraseology and terminology employed herein are for the purpose of description and should not be regarded as limiting.

It is important, therefore, that the scope of the invention is not construed as being limited by the illustrative embodiments set forth herein. Other variations are possible within the scope of the present invention as defined in the appended claims.

1-49. (canceled)

50. A polycrystalline semiconductor compound for use in a solid-state neutron detector, comprising a particulate semiconductor material sensitive to neutron and alpha particles radiation imbedded in a binder, said particulate semiconductor material containing at least one element sensitive to neutron and alpha particles radiation, selected from ¹⁰Boron, ⁶Lithium, ¹¹³Cadmium, ¹⁵⁷Gadolinium and ¹⁹⁹Mercury,
said binder possessing one of the following features:
(i) said binder is an organic polymer binder comprising at least one polymer selected from polystyrene, polypropylene, Humiseal™ and Nylon-6;
(ii) said binder is an inorganic binder selected from B₂O₃, PbO/B₂O₃/, Bi₂O₃/PbO, Borax glass, Bismuth Borate glass and Boron Oxide based glass.

51. The polycrystalline semiconductor compound of claim 50 wherein a mean grain size of said particulate semiconductor material is in the range of 10 nm to 100 microns.

52. The polycrystalline semiconductor compound of claim 50 wherein said particulate semiconductor material is selected from the group comprising: BC, BP, BN, BaB₂O₄, LiF, LiNbO₃, Li₂B₂O₄, Li₂B₄O₇, Li₃PO₄, CdS, CdSe, CdTe, Gd₂S₃, Gd₂O₃, Gd₂F₃, CdZnTe, HgBrI and HgI₂.

53. The polycrystalline semiconductor compound of claim 50 wherein a ratio of said particulate semiconductor material to said binder is in the range of 5:95 in weight % to 95:5 in weight %.

54. A solid-state neutron and alpha particles detector having an active region formed of a polycrystalline semiconductor compound comprising a particulate semiconductor material sensitive to neutron and alpha particles radiation imbedded in a binder, said particulate semiconductor material containing at least one element sensitive to neutron and alpha particles radiation, selected from a group including ¹⁰Boron, ⁶Lithium, ¹¹³Cadmium, ¹⁵⁷Gadolinium and ¹⁹⁹Mercury, said semiconductor compound being sandwiched between an electrode assembly configured to detect the neutron and alpha particles interacting with the bulk of said active region,
said binder possessing one of the following features:
(i) said binder is an organic polymer binder comprising at least one polymer selected from polystyrene, polypropylene, Humiseal™ and Nylon-6;
(ii) said binder is an inorganic binder selected from B₂O₃, PbO/B₂O₃/, Bi₂O₃/PbO, Borax glass, Bismuth Borate glass and Boron Oxide based glass.

55. The solid-state neutron and alpha particles detector of claim 54 wherein a mean grain size of said particulate semiconductor material is in the range of 10 nm to 100 microns.

56. The solid-state neutron and alpha particles detector of claim 54 wherein said particulate semiconductor material is selected from the group comprising: BC, BP, BN, BaB₂O₄, LiF, LiNbO₃, Li₂B₂O₄, Li₂B₄O₇, Li₃PO₄, CdS, CdSe, CdTe, Gd₂S₃, Gd₂O₃, Gd₂F₃, CdZnTe, HgBrI and HgI₂.

57. The solid-state neutron and alpha particles detector of claim 54 wherein a ratio of said particulate semiconductor material to said binder is in the range of 5:95 in weight % to 95:5 in weight %.

58. The solid-state neutron and alpha particles detector of claim 54 wherein said electrode assembly comprises a continuous upper electrode, a bottom electrode associated with a detection pixilated substrate, and an electronic readout system coupled to the upper electrode and the bottom electrode.

59. The solid-state neutron and alpha particles detector of claim 58 wherein said detection pixilated substrate is a focal pixel array constituted by an assembly of pixel elements comprising a set of stripe electrodes mounted on a top surface of a substrate containing readout electronic circuits used for analyzing detected signals.

60. The solid-state neutron and alpha particles detector of claim 59 wherein each pixel element is based on a readout electronic element selected from a Complementary Metal Oxide Semiconductor (C-MOS) chip, a charge coupled device (CCD) and Thin Film Transistor (TFT) electronics, all configured for obtaining an electron/hole current generated in the active region.

61. The solid-state neutron and alpha particles detector of claim 58 wherein said continuous upper electrode is made of at least one material selected from Aquadag, copper and aluminum.

62. An imaging system for imaging an object, the system comprising:
(a) a solid-state neutron and alpha particles detector placed in a location to be exposed to a stream of neutrons passing through said object, said solid-state neutron and alpha particles detector having an active region made of a polycrystalline semiconductor compound comprising a particulate semiconductor material sensitive to neutron and alpha particles radiation imbedded in a binder, said particulate semiconductor material containing at least one element sensitive to neutron and alpha particles radiation, selected from a group including ¹⁰Boron, ⁶Lithium, ¹¹³Cadmium, ¹⁵⁷Gadolinium and ¹⁹⁹Mercury, said semiconductor compound being sandwiched between a continuous upper electrode and a bottom electrode associated with a detection pixilated substrate constituted by an array of pixel elements,
said binder possessing one of the following features:
(i) said binder is an organic polymer binder comprising at least one polymer selected from polystyrene, polypropylene, Humiseal™ and Nylon-6;
(ii) said binder is an inorganic binder selected from B₂O₃, PbO/B₂O₃/, Bi₂O₃/PbO, Borax glass, Bismuth Borate glass and Boron Oxide based glass;
(b) a processing system coupled to said detection pixilated substrate and adapted for reading the current, performing image processing and generating a signal indicative of said object; and
(c) an image display coupled to said processing system and configured for obtaining said signal, thereby displaying the object.

63. The imaging system of claim 62 wherein a mean grain size of said particulate semiconductor material is in the range of 10 nm to 100 microns.

64. The imaging system of claim 62 wherein said particulate semiconductor material is selected from the group comprising: BC, BP, BN, BaB₂O₄, LiF, LiNbO₃, Li₂B₂O₄, Li₂B₄O₇, Li₃PO₄, CdS, CdSe, CdTe, Gd₂S₃, Gd₂O₃, Gd₂F₃, CdZnTe, HgBrI and HgI₂.

65. The imaging system of claim 62 wherein a ratio of said particulate semiconductor material to said binder is in the range of 5:95 in weight % to 95:5 in weight %.

66. The imaging system of claim 62 wherein said pixel elements comprise a set of stripe electrodes mounted on an upper surface of a substrate containing readout electronic circuits used for analyzing detected signals.

67. The imaging system of claim 62 wherein each pixel element is based on a readout electronic element selected from a Complementary Metal Oxide Semiconductor (C-MOS) chip, a charge coupled device (CCD) and Thin Film Transistor (TFT) electronics, all configured for obtaining an electron/hole current generated in said active region.

68. A method of fabrication of a solid state neutron and alpha particles detector, comprising:
(a) providing a polycrystalline semiconductor compound comprising a particulate semiconductor material sensitive to neutron and alpha particles radiation imbedded in a binder, said particulate semiconductor material containing at least one element sensitive to neutron and alpha particles radiation, selected from a group including ¹⁰Boron, ⁶Lithium, ¹¹³Cadmium, ¹⁵⁷Gadolinium and ¹⁹⁹Mercury;
said binder possessing one of the following features:
(i) said binder is an organic polymer binder comprising at least one polymer selected from polystyrene, polypropylene, Humiseal™ and Nylon-6;
(ii) said binder is an inorganic binder selected from B₂O₃, PbO/B₂O₃/, Bi₂O₃/PbO, Borax glass, Bismuth Borate glass and Boron Oxide based glass;
(b) attaching the polycrystalline semiconductor compound to a detection pixilated substrate constituted by an array of pixel elements; and
(c) depositing a continuous layer of conductive material on said bulk plate, thereby to form a continuous electrode of the detector.

69. The method of claim 68 wherein said providing of the polycrystalline semiconductor compound comprises preparing polycrystalline semiconductor material sensitive to neutron and alpha particles radiation, providing the binder, and mixing the polycrystalline semiconductor particles with the binder.

70. The method of claim 68 wherein said polycrystalline semiconductor compound is prepared as slurry, and said attaching of the slurry is carried out by a coating method.

71. The method of claim 70 wherein said coating method is either Dr. Blade coating method.

72. The method of claim 68 wherein said polycrystalline semiconductor compound is prepared as bulk plate, and said attaching of the plate is carried out by gluing.

73. The method of claim 72 wherein said gluing is carried out by a “flip-chip” technology.

74. The method of claim 68 wherein a mean grain size of said particulate semiconductor material is in the range of 10 nm to 100 microns.

75. The method of claim 68 wherein said particulate semiconductor material is selected from the group comprising: BC, BP, BN, BaB₂O₄, LiF, LiNbO₃, Li₂B₂O₄, Li₂B₄O₇, Li₃PO₄, CdS, CdSe, CdTe, Gd₂S₃, Gd₂O₃, Gd₂F₃, CdZnTe, HgBrI and HgI₂.

76. The method of claim 68 wherein a ratio of said particulate semiconductor material to said binder is in the range of 5:95 in weight % to 95:5 in weight %.

77. A method of detecting neutrons and alpha particles, the method comprising:
(a) positioning a solid state neutron and alpha particles detector in a location to allow the detector to intercept a stream of neutrons and/or alpha particles, said solid-state neutron and alpha particles detector having an active region made of a polycrystalline semiconductor compound comprising a particulate semiconductor material sensitive to neutron and alpha particles radiation imbedded in a binder, said particulate semiconductor material containing at least one element sensitive to neutron and alpha particles radiation, selected from a group including ¹⁰Boron, ⁶Lithium, ¹¹³Cadmium, ¹⁵⁷Gadolinium and ¹⁹⁹Mercury, said semiconductor compound being sandwiched between a continuous upper electrode and a bottom electrode associated with a detection pixilated substrate constituted by an array of pixel elements,
said binder possessing one of the following features:
(i) said binder is an organic polymer binder comprising at least one polymer selected from polystyrene, polypropylene, Humiseal™ and Nylon-6;
(ii) said binder is an inorganic binder selected from B₂O₃, PbO/B₂O₃/, Bi₂O₃/PbO, Borax glass, Bismuth Borate glass and Boron Oxide based glass;
(b) applying electric field is applied between the upper and bottom electrodes by applying high voltage thereacross, and
(c) reading the current from the detection pixilated substrate.

78. The method of detecting neutrons and alpha particles of claim 77 wherein said particulate semiconductor material is selected from the group comprising: BC, BP, BN, BaB₂O₄, LiF, LiNbO₃, Li₂B₂O₄, Li₂B₄O₇, Li₃PO₄, CdS, CdSe, CdTe, Gd₂S₃, Gd₂O₃, Gd₂F₃, CdZnTe, HgBrI and HgI₂.

79. A method for imaging an object containing elements sensitive to neutron radiation, comprising:
(a) providing a solid-state neutron and alpha particles detector having an active region made of a polycrystalline semiconductor compound comprising a particulate semiconductor material sensitive to neutron radiation imbedded in a binder, said particulate semiconductor material containing at least one element sensitive to neutron and alpha particles radiation, selected from a group including ¹⁰Boron, ⁶Lithium, ¹¹³Cadmium, ¹⁵⁷Gadolinium and Mercury, said semiconductor compound being sandwiched between a continuous upper electrode and a bottom electrode associated with a detection pixilated substrate constituted by an array of pixel elements,
said binder possessing one of the following features:
(i) said binder is an organic polymer binder comprising at least one polymer selected from polystyrene, polypropylene, Humiseal™ and Nylon-6;
(ii) said binder is an inorganic binder selected from B₂O₃, PbO/B₂O₃/, Bi₂O₃/PbO, Borax glass, Bismuth Borate glass and Boron Oxide based glass;
(b) placing said solid-state neutron and alpha particles detector in a location to allow the detector to intercept a stream of neutrons, said solid-state neutron passing through said object
(c) applying electric field between the upper and bottom electrodes by applying high voltage thereacross,
(d) reading the current from the detection pixilated substrate;
(e) performing image processing and generating a signal indicative of said object; and
(f) displaying at least a part of the object containing elements sensitive to neutron radiation.

80. The method for imaging of claim 79 wherein said particulate semiconductor material is selected from the group comprising: BC, BP, BN, BaB₂O₄, LiF, LiNbO₃, Li₂B₂O₄, Li₂B₄O₇, Li₃PO₄, CdS, CdSe, CdTe, Gd₂S₃, Gd₂O₃, Gd₂F₃, CdZnTe, HgBrI and HgI₂.
